(19) United States
(12) Patent Application Publication
(10) Pub. No.: US 2026/0247615 A1
(43) Pub. Date: Aug. 20, 2026

(54) SEMICONDUCTOR DEVICE AND METHOD OF MANUFACTURING SEMICONDUCTOR DEVICE

(71) Applicant: SK hynix Inc., Icheon-si Gyeonggi-do (KR)

(72) Inventor: Seung Ju OH, Icheon-si Gyeonggi-do (KR)

(73) Assignee: SK hynix Inc., Icheon-si Gyeonggi-do (KR)

(21) Appl. No.: 19/202,617

(22) Filed: May 8, 2025

(30) Foreign Application Priority Data
Feb. 18, 2025 (KR) 10-2025-0020951

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

A semiconductor device includes a stack including a plurality of first insulating layers alternately stacked with a plurality of second insulating layers, a contact plug extending through the stack, a gate structure surrounding the stack and including a plurality of conductive layers alternately stacked with the plurality of first insulating layers, a separation structure located between the stack and the gate structure, and a contact pattern extending around the separation structure, and electrically connecting the contact plug and a first conductive layer among the plurality of conductive layers.

### CROSS-REFERENCE TO RELATED APPLICATION

The present application claims priority under 35 U.S.C. § 119(a) to Korean Patent Application No. 10-2025-0020951, filed in the Korean Intellectual Property Office on Feb. 18, 2025, which application is incorporated herein by reference in its entirety.

### BACKGROUND

### 1. Technical Field

The present disclosure relates to an electronic device and a method of manufacturing the electronic device, including but not limited to a semiconductor device and a method of manufacturing the semiconductor device.

### 2. Related Art

Integration density of a semiconductor device is determined by an area occupied by a unit memory cell. As improvements in an integration density of semiconductor devices in which memory cells are formed as a single layer on a substrate reach a limit, three-dimensional semiconductor devices in which memory cells are stacked on a substrate are under development. Various structures and manufacturing methods are being developed to improve operation reliability of semiconductor devices.

### SUMMARY

According to an embodiment of the present disclosure, a semiconductor device may include a stack including a plurality of first insulating layers alternately stacked with a plurality of second insulating layers, a contact plug extending through the stack, a gate structure surrounding the stack and including a plurality of conductive layers alternately stacked with the plurality of first insulating layers, a separation structure located between the stack and the gate structure, and a contact pattern extending around the separation structure and electrically connecting the contact plug and a first conductive layer among the conductive layers.

According to an embodiment of the present disclosure, a semiconductor device may include a stack including a plurality of first insulating layers alternately stacked with a plurality of second insulating layers, a contact plug extending through the stack, a gate structure surrounding the stack and including a plurality of conductive layers alternately stacked with the plurality of first insulating layers, a separation structure located between the stack and the gate structure, and including a plurality of pillars arranged around the contact plug and a plurality of extensions interconnecting the pillars, and a contact pattern extending around the separation structure and electrically connecting the contact plug and a first conductive layer among the conductive layers.

According to an embodiment of the present disclosure, a method of manufacturing a semiconductor device may include forming a stack by alternately stacking a plurality of first material layers with a plurality of second material layers, forming a plurality of holes extending through the stack, forming a sacrificial layer in each of the plurality of holes, forming a contact hole located in a region delineated by the plurality of holes and extending through the stack, forming a preliminary contact spacer in the contact hole, forming a first opening, through which a second material layer is exposed, by etching a surface at one end of the preliminary contact spacer, resulting in a contact spacer, forming a second opening, through which the sacrificial layers are exposed, by selectively removing the second material layer through the first opening, and forming a conductive material in the second opening, the first opening, and within the contact spacer.

### BRIEF DESCRIPTION OF THE DRAWINGS

FIG. 1A, FIG. 1B, FIG. 1C, and FIG. 1D illustrate a semiconductor device according to an embodiment of the present disclosure.

FIG. 2A and FIG. 2B illustrate a semiconductor device according to an embodiment of the present disclosure.

FIG. 3A, FIG. 3B, FIG. 3C, and FIG. 3D illustrate a semiconductor device according to an embodiment of the present disclosure.

FIG. 4A, FIG. 4B, FIG. 5A, FIG. 5B, FIG. 5C, FIG. 6A, FIG. 6B, FIG. 6C, FIG. 7A, FIG. 7B, FIG. 7C, FIG. 8A, FIG. 8B, FIG. 8C, FIG. 8D, FIG. 9A, FIG. 9B, and FIG. 9C illustrate a semiconductor device formed utilizing a method of manufacturing a semiconductor device according to an embodiment of the present disclosure.

FIG. 10A, FIG. 10B, FIG. 10C, FIG. 11A, FIG. 11B, FIG. 11C, FIG. 12A, FIG. 12B, FIG. 12C, FIG. 13A, FIG. 13B, FIG. 13C, FIG. 13D, FIG. 14A, FIG. 14B, and FIG. 14C illustrate a semiconductor device formed utilizing a method of manufacturing a semiconductor device according to an embodiment of the present disclosure.

FIG. 15A, FIG. 15B, FIG. 16A, FIG. 16B, FIG. 17A, FIG. 17B, and FIG. 17C illustrate a semiconductor device formed utilizing a method of manufacturing a semiconductor device according to an embodiment of the present disclosure.

The drawings are not necessarily drawn to scale and include differing quantities of various structures between the cross-sectional views and corresponding plan views, and complete versions of some structures are not shown between the cross-sectional views and corresponding plan views.

### DETAILED DESCRIPTION

An embodiment of the present disclosure provides a semiconductor device and a method of manufacturing the semiconductor device having a stable structure and an improved characteristic.

According to the present disclosure, a semiconductor device having a stable structure and improved reliability may be provided.

Embodiments of the present disclosure are described with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification. Common or overlapping subject matter is not repeated.

Terms such as “horizontal,” “top,” “bottom,” “under,” “over,” “on,” “side,” “lower,” “lowermost,” “level,” and other terms implying relative spatial relationship or orientation are utilized only for the purpose of ease of description or reference to a drawing and are not otherwise limiting.

The cross-hatching throughout the figures illustrates corresponding or similar areas between the figures rather than indicating the materials associated with the areas.

The drawings include reference numerals/names that indicate an object and, within parentheses next to the reference numeral/name, one or more features, elements, sacrificial materials, or holes utilized during the process of forming the object. For example, the lead line for 440S(SPH1) indicates sacrificial layers 440S formed within first support holes SPH1, such as shown in FIG. 5A. The lead line for 450(450A/CTH) indicates the contact spacer 450 formed from the preliminary contact spacer 450A that is formed within the contact hole CTH, such as shown in FIG. 6A and FIG. 6B. The lead line for 460S(CTH, OP1,OP2) indicates the contact sacrificial layer 460S formed within the contact hole CTH, the first opening OP1, and the second opening OP2, such as shown in FIG. 6A, FIG. 6B, and FIG. 6C.

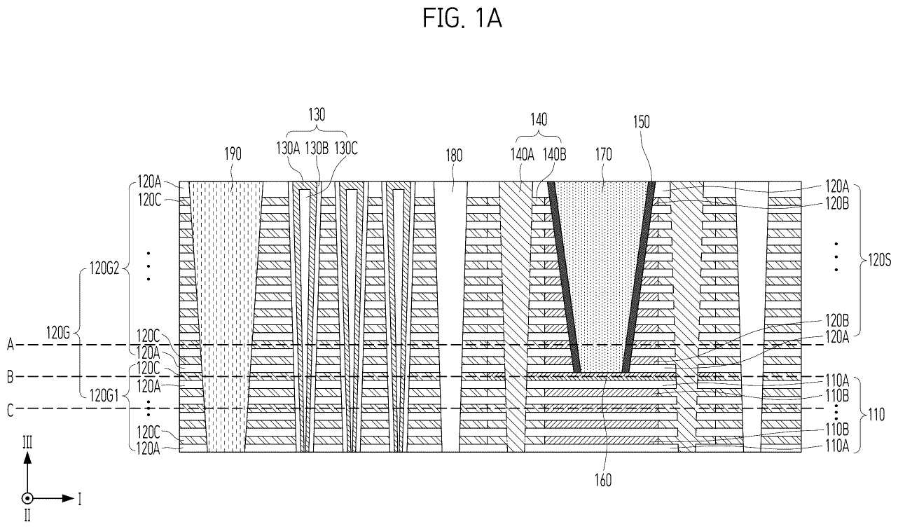

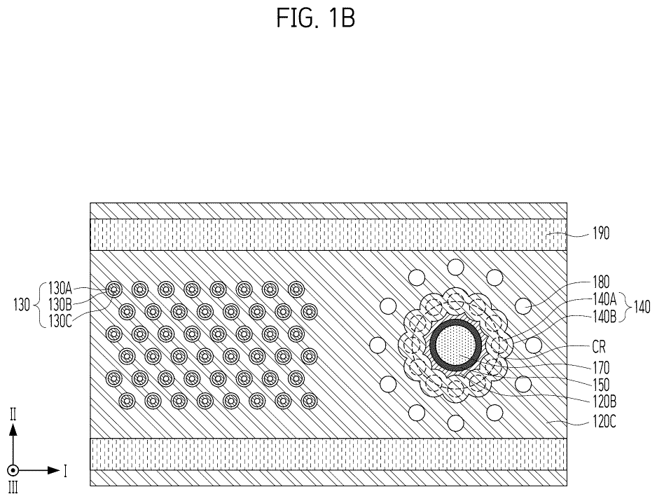

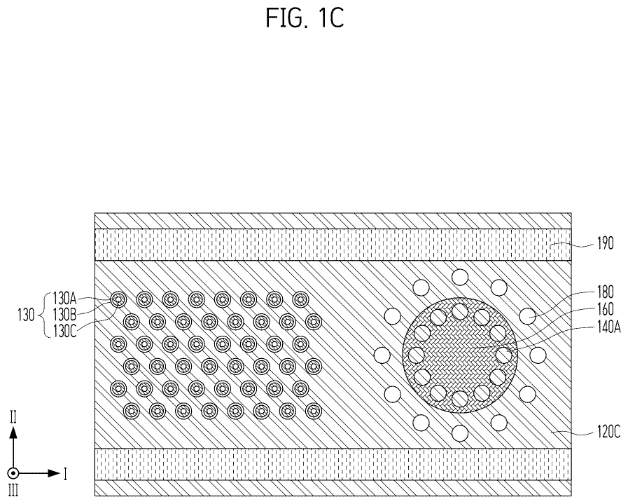

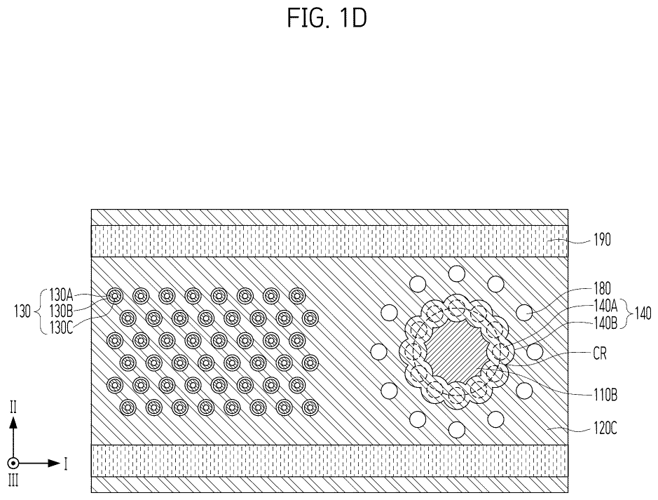

FIG. 1A, FIG. 1B, FIG. 1C, and FIG. 1D illustrate a semiconductor device according to an embodiment of the present disclosure. FIG. 1A is a cross-sectional view, FIG. 1B is a plan view at level A of FIG. 1A, FIG. 1C is a plan view at level B of FIG. 1A, and FIG. 1D is a plan view at level C of FIG. 1A.

Referring to FIG. 1A to FIG. 1D, the semiconductor device includes a support structure 110, a stack 120S, a gate structure 120G, channel structures 130, separation structures 140, a contact spacer 150, a contact pattern 160, a contact plug 170, supports 180, and slit structures 190.

The support structure 110 include first insulating layers 110A alternately stacked with second insulating layers 110B. The support structure 110 supports the semiconductor device during a process of forming the gate structure 120G. The first insulating layers 110A and the second insulating layers 110B may include different materials. For example, the first insulating layers 110A may include an insulating material such as an oxide, and the second insulating layers 110B may include an insulating material such as a nitride.

The stack 120S is located on the support structure 110. The stack 120S includes first insulating layers 120A alternately stacked with second insulating layers 120B. The insulating layers 120A and 120B correspond to the second insulating layers 110A and 110B of the support structure 110. The first insulating layers 120A may include an insulating material such as an oxide, and the second insulating layers 120B may include an insulating material such as a nitride.

The gate structure 120G surrounds the stack 120S. For example, the gate structure 120G surrounds the stack 120S and the support structure 110. The gate structure 120G includes first insulating layers 120A alternately stacked with conductive layers 120C. The gate structure 120G includes a first section 120G1 located at levels corresponding to the levels of the support structure 110 and a second section 120G2 located at levels corresponding to the levels of the stack 120S.

The conductive layers 120C are gate lines such as a source selection line, a word line, and a drain selection line. A source selection transistor, a memory cell, or a drain selection transistor are located in a region where the channel structures 130 and the conductive layers 120C intersect. For example, one memory string includes at least one source selection transistor, a plurality of memory cells, and at least one drain selection transistor stacked along the channel structure 130. The first insulating layers 120A may include an insulating material such as an oxide. The conductive layers 120C may include a conductive material such as tungsten, molybdenum, or polysilicon.

The channel structures 130 extend through the gate structure 120G. Each of the channel structures 130 includes a channel layer 130A and a memory layer 130B surrounding the channel layer 130A. Each of the channel structures 130 includes an insulating core 130C surrounded by the channel layer 130A. The channel layer 130A may include a semiconductor material such as polysilicon or germanium. The insulating core 130C may include an insulating material such as an oxide.

The contact plug 170 is located on the support structure 110. In other words, the support structure 110 is located under the contact plug 170. The contact plug 170 extends through the stack 120S. The contact plug 170 is connected to one of the conductive layers 120C of the gate structure 120G. The conductive layer 120C connected to the contact plug 170 is referred to as a first conductive layer. The contact plug 170 may include a conductive material such as tungsten.

The contact spacer 150 surrounds a sidewall of the contact plug 170. The contact spacer 150 insulates the contact plug 170 and the conductive layers 120C except for the first conductive layer electrically connected to the contact plug 170. The contact spacer 150 may include an insulating material such as an oxide.

The separation structures 140 extend through the stack 120S and the gate structure 120G. For example, the separation structures 140 extend through the stack 120S and the gate structure 120G and extend through the support structure 110 and the gate structure 120G. The separation structure 140 separates the gate structure 120G from the stack 120S. For example, the separation structure 140 separates a region where the support structure 110 and the stack 120S are located from a region where the gate structure 120G is located. In other words, the separation structure 140 separates a region where the contact plug 170 is located from a region where the gate structure 120G is located.

The separation structure 140 includes pillars 140A arranged around the contact plug 170 and a plurality of extensions 140B, each extension 140B located at a level corresponding to a level of a conductive layer 120C except for the first conductive layer. The plurality of extensions 140B interconnects the pillars 140A. The extensions 140B are interconnected or joined in a plane to form a closed region CR within the plane. The support structure 110 and the stack 120S are located within the closed region CR. The second insulating layers 110B of the support structure 110 and the second insulating layers 120B of the stack 120S are located at levels corresponding to levels of the extensions 140B. The separation structure 140 may include an insulating material such as an oxide.

The contact pattern 160 is located between the support structure 110 and the stack 120S. The contact pattern 160 extends around the separation structures 140. For example, the contact pattern 160 extends between the pillars 140A. The contact pattern 160 electrically connects the contact plug 170 and the first conductive layer among the conductive layers 120C. The contact pattern 160 is integral with or connected to the contact plug 170. Although a boundary or surface between the contact pattern 160 and the contact plug 170 is shown in FIG. 1A, a boundary or surface may not exist between the contact pattern 160 and the contact plug 170. The contact pattern 160 may include a conductive material such as tungsten.

According to an embodiment of the present disclosure, the contact pattern 160 extends around the separation structure 140 (not shown) and electrically connects the first conductive layer and the contact plug 170. In other words, the contact pattern 160 extends in a horizontal direction through or around the separation structure 140 and electrically connects the contact plug 170 and the first conductive layer.

The supports 180 extend through the gate structure 120G. The supports 180 are spaced apart from the separation structure 140. The supports 180 may have a structure similar to the channel structures 130. For example, each of the supports 180 includes at least one of a dummy channel layer, a dummy memory layer surrounding the dummy channel layer, and a dummy insulating core surrounded by the dummy channel layer. The supports 180 may include an insulating material such as an oxide. Alternatively, the supports 180 may include a conductive layer such as tungsten and an insulating layer surrounding the conductive layer.

The slit structure 190 extends through the gate structure 120G. The term “slit structure” does not indicate that the structure is a slit but rather is so named because the process of forming the slit structure utilizes a slit. A slit structure may be referred to as a divider. The slit structure 190 may include an insulating material, a conductive material, or a semiconductor material.

According to the structure described with respect to FIG. 1A to FIG. 1D, the separation structure 140 separates the region where the contact plug 170 is located and the region where the gate structure 120G is located. The contact pattern 160 extends in a horizontal direction through or around the separation structure 140, and electrically connects the contact plug 170 with the first conductive layer among the conductive layers 120C of the gate structure 120G.

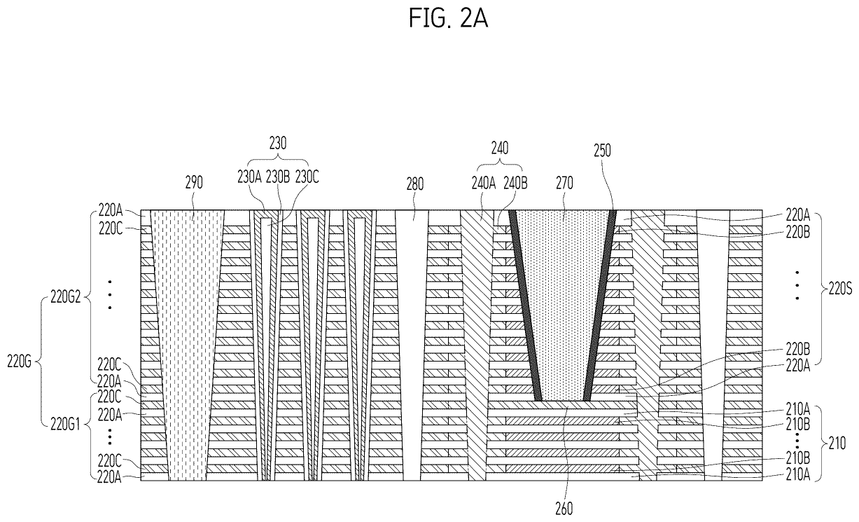

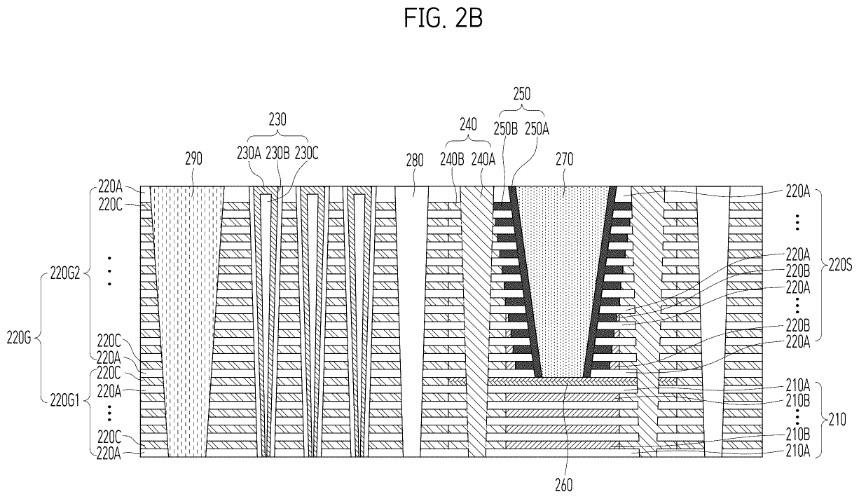

FIG. 2A and FIG. 2B illustrate a semiconductor device according to an embodiment of the present disclosure. Hereinafter, a contact that overlaps the content described above is omitted.

Referring to FIG. 2A and FIG. 2B, the semiconductor device includes a support structure 210, a stack 220S, a gate structure 220G, channel structures 230, separation structures 240, a contact spacer 250, a contact pattern 260, a contact plug 270, supports 280, and slit structures 290.

The support structure 210 includes first insulating layers 210A alternately stacked with second insulating layers 210B. The first insulating layers 210A may include an insulating material such as an oxide, and the second insulating layers 210B may include an insulating material such as a nitride.

The stack 220S may be located on the support structure 210. The stack 220S includes first insulating layers 220A alternately stacked with second insulating layers 220B. The insulating layers 220A and 220B correspond to the insulating layers 210A and 210B of the support structure 210. The first insulating layers 220A may include an insulating material such as an oxide, and the second insulating layers 220B may include an insulating material such as a nitride.

The gate structure 220G surrounds the stack 220S. For example, the gate structure 220G surrounds the stack 220S and the support structure 210. The gate structure 220G includes first insulating layers 220A alternately stacked with conductive layers 220C. The gate structure 220G includes a first section 220G1 located at levels corresponding to the levels of the support structure 210 and a second section 220G2 located at levels corresponding to the stack 220S.

The channel structures 230 extends through the gate structure 220G. Each of the channel structures 230 includes a channel layer 230A, a memory layer 230B surrounding the channel layer 230A, and an insulating core 230C surrounded by the channel layer 230A.

The contact plug 270 is located on the support structure 210. The contact plug 270 extends through the stack 220S and is connected to one of the conductive layers 220C of the gate structure 220G. The conductive layer 220C connected to the contact plug 270 is referred to as a first conductive layer.

The contact spacer 250 surrounds a sidewall of the contact plug 270. The contact spacer 250 insulates the contact plug 270 and the conductive layers 220C except for the first conductive layer electrically connected to the contact plug 270.

The separation structure 240 extends through the stack 220S and the gate structure 220G. The separation structure 240 separates the gate structure 220G from the stack 220S. For example, the separation structure 240 separates a region where the contact plug 270 is located from a region where the gate structure 220G is located. The separation structure 240 includes pillars 240A arranged around the contact plug 270 and a plurality of extensions 240B, each extension 240B located at a level corresponding to the conductive layers 220C except for the first conductive layer. The plurality of extensions 240B interconnects the pillars 240A.

The contact pattern 260 is located between the support structure 210 and the stack 220S. The contact pattern 260 extend around the separation structure 240. For example, the contact pattern 260 extends between the pillars 240A. The contact pattern 260 electrically connects the contact plug 270 with the first conductive layer among the conductive layers 220C.

The supports 280 extend through the gate structure 220G. The supports 280 may have a structure similar to the channel structures 230. The supports 280 may include an insulating material such as an oxide. The supports 280 may include a conductive layer such as tungsten and an insulating layer surrounding the conductive layer. The slit structure 290 extends through the gate structure 220G. The slit structure 290 may include an insulating material, a conductive material, or a semiconductor material.

According to the structure described with respect to FIG. 2A and FIG. 2B, the contact pattern 260 is integral with or connected to the first conductive layer connected to the contact plug 270 among the conductive layers 220C. The first conductive layer extends through or around the separation structures 240 and is electrically connected to the contact plug 270.

The contact spacer 250 includes a body 250A and protrusions 250B protruding or extending from the body 250A. The protrusions 250B extend in a horizontal direction relative to the drawing and insulate the contact plug 270 from the conductive layers 220C by establishing a margin between the contact plug 270 and the conductive layers 220C in the horizontal direction.

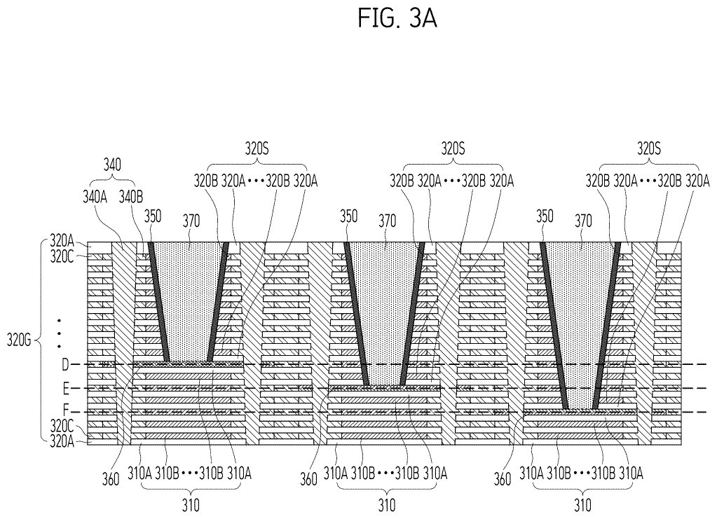

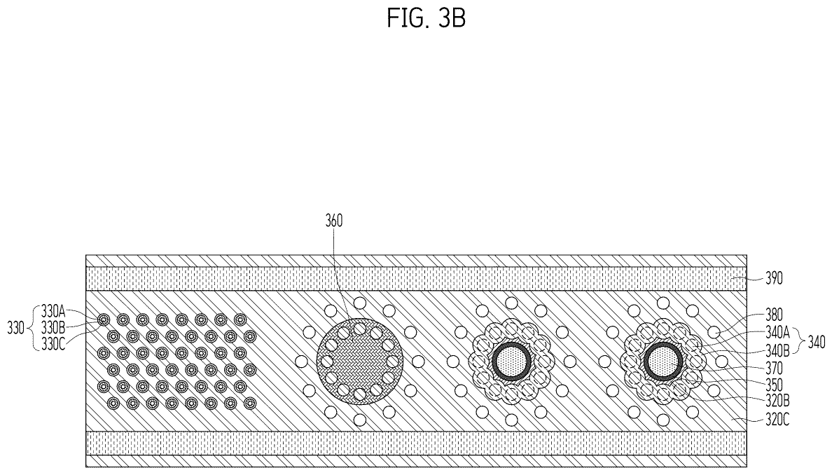

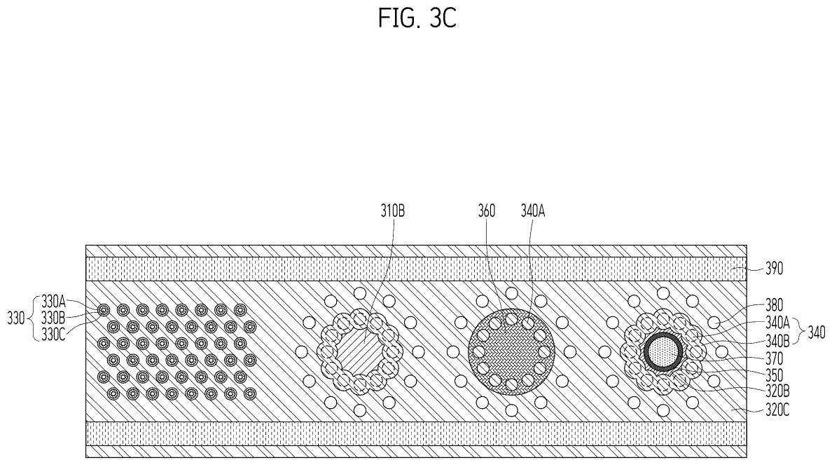

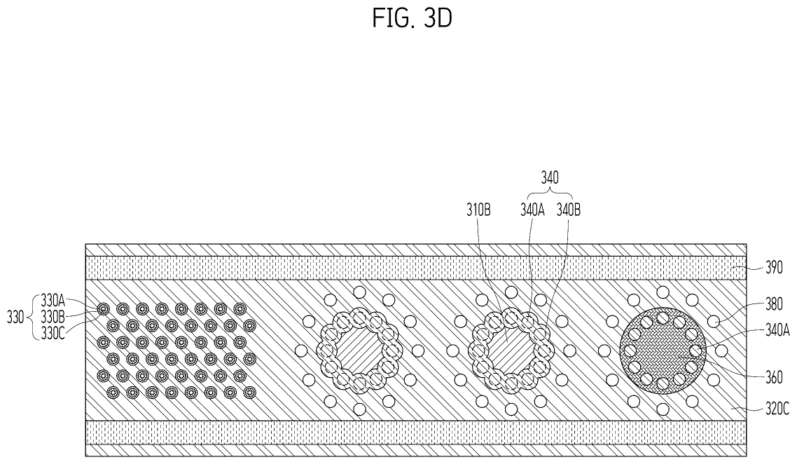

FIG. 3A, FIG. 3B, FIG. 3C, and FIG. 3D illustrate a semiconductor device according to an embodiment of the present disclosure. FIG. 3A is a cross-sectional view, FIG. 3B is a plan view at level D of FIG. 3A, FIG. 3C is a plan view at level E of FIG. 3A, and FIG. 3D is a plan view at level F of FIG. 3A. Hereinafter, a contact that overlaps the content described above is omitted.

Referring to FIG. 3A to FIG. 3D, the semiconductor device includes a support structures 310, a gate structure 320G, stacks 320S, channel structures 330, separation structures 340, contact spacers 350, contact patterns 360, contact plugs 370, supports 380, and slit structures 390.

Each of the support structures 310 include first insulating layers 310A alternately stacked with second insulating layers 310B. Each support structure 310 has a different height. For example, each of the support structures 310 includes a different quantity of insulating layers 310A alternately stacked with insulating layers 310B.

The stacks 320S are located on corresponding support structures 310. Each of the stacks 320S includes first insulating layers 320A insulating layers second insulating layers 320B. Each stack 320S has a different height. The stacks 320S may have a height inversely proportional to a corresponding support structures 310. For example, the support structure 310 having a relatively large height corresponds to the stack 320S having a relatively small height.

The gate structure 320G surrounds the support structures 310 and the stacks 320S. The gate structure 320G includes first insulating layers 320A insulating layers conductive layers 320C.

Each of the contact plugs 370 extends through a corresponding stack 320S and is connected to one of the conductive layers 320C of the gate structure 320G. Each of the contact plugs 370 is located on a corresponding support structures 310. For example, the contact plugs 370 may be located in a region corresponding to the support structures 310, respectively. The quantity of the contact plugs 370 is equal to the quantity of the support structures 310. The contact plugs 370 have different heights. Each of the contact plugs 370 may have a height inversely proportional to a corresponding support structure 310 and a height proportional to a corresponding stack 320S. For example, when the height of the contact plug 370 is small, the height of the corresponding support structure 310 is large, and the height of the corresponding stack 320S is small. Because the gate structure 320G has a constant height, the height of a contact plug 270, that has the same height as a corresponding stack 320S, plus the height of the corresponding support structure 310 is the same as the height of the gate structure 320G.

Each of the contact spacers 350 surrounds a sidewall of a corresponding contact plug 370. The contact spacers 350 insulate the contact plug 370 and conductive layers 320C except for the conductive layer 320C electrically connected to the contact plug 370.

Each of the separation structures 340 is located between a corresponding stack 320S and the gate structure 320G. Each separation structure 340 separates a region where a corresponding contact plug 370 is located from a region where the gate structure 320G is located. The separation structure 340 includes pillars 340A arranged around the contact plug 370 and extensions 340B protruding from the pillars 340A in a horizontal direction.

Each of the contact patterns 360 is located between a corresponding support structure 310 and a corresponding stack 320S. The contact patterns 360 extend through or around the separation structures 340. The contact patterns 360 electrically connect the conductive layers 320C and corresponding contact plugs 370. The contact pattern 360 is integral with or connected to the contact plug 370. For example, the contact pattern 360 is integral with the first conductive layer among the conductive layers 320C and is connected to the contact plug 370.

According to the structure described with respect to FIG. 3A to FIG. 3D, the contact plugs 370 are located on corresponding support structures 310. For example, the contact plugs 370 are located in a region corresponding to the support structures 310. The quantity of the contact plugs 370 is equal to the quantity of the support structures 310. The support structures 310 have different heights corresponding to contact plugs 370 having different heights, thereby improving support or supporting force under the contact plugs 370.

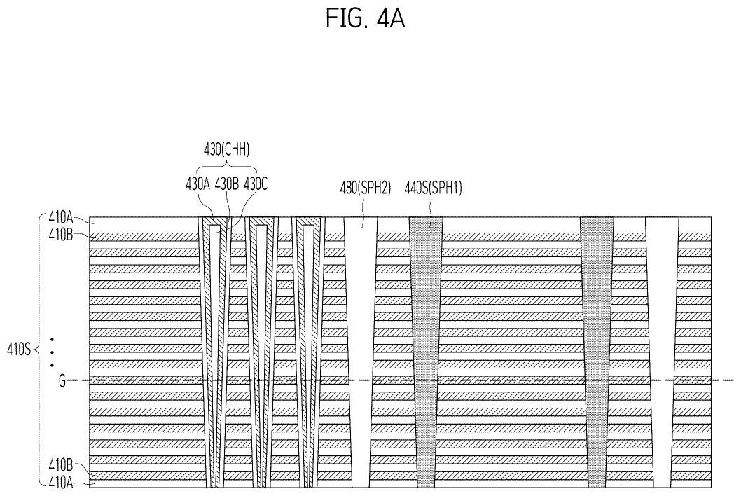

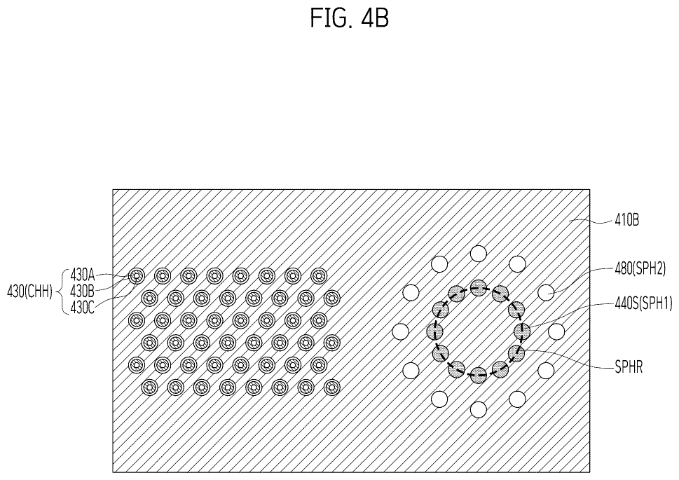

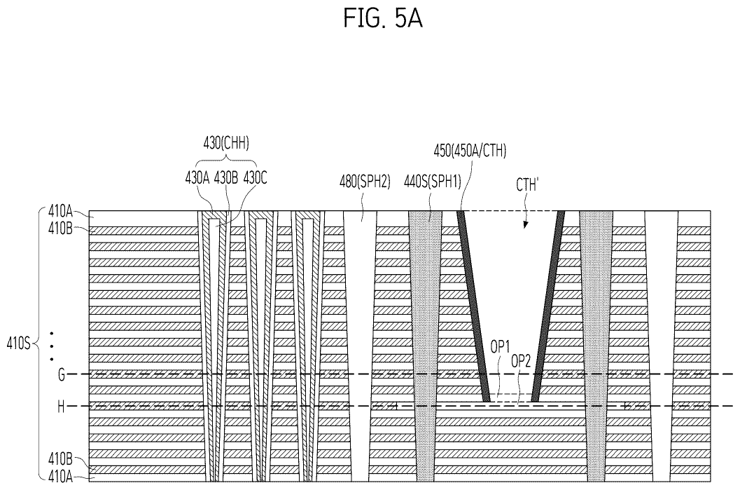

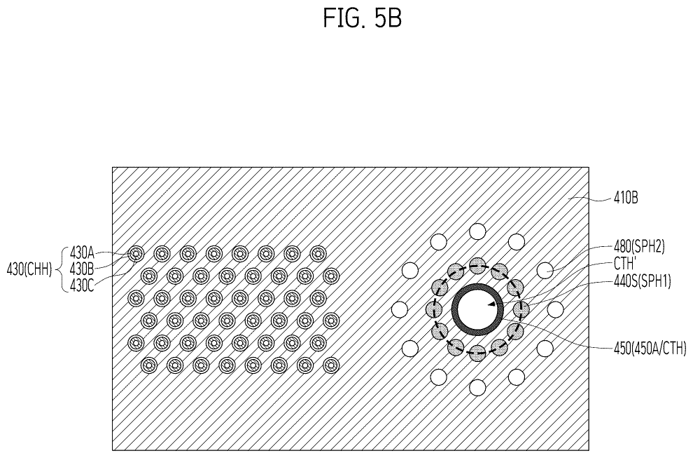

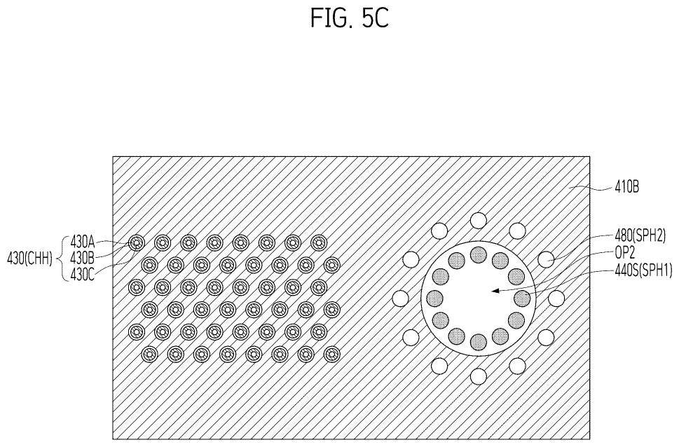

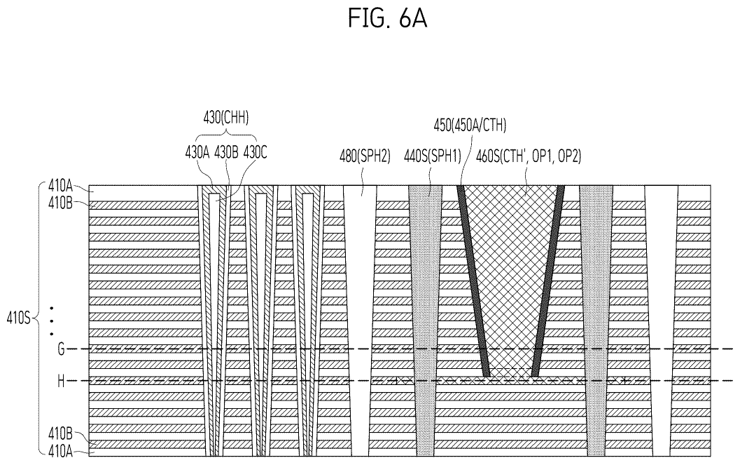

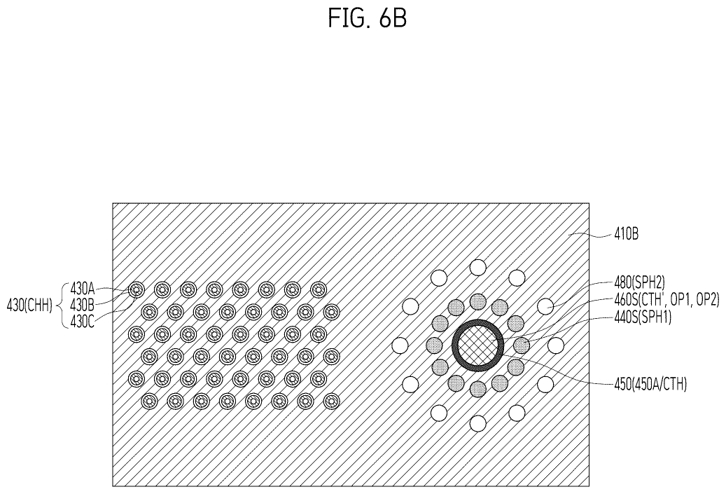

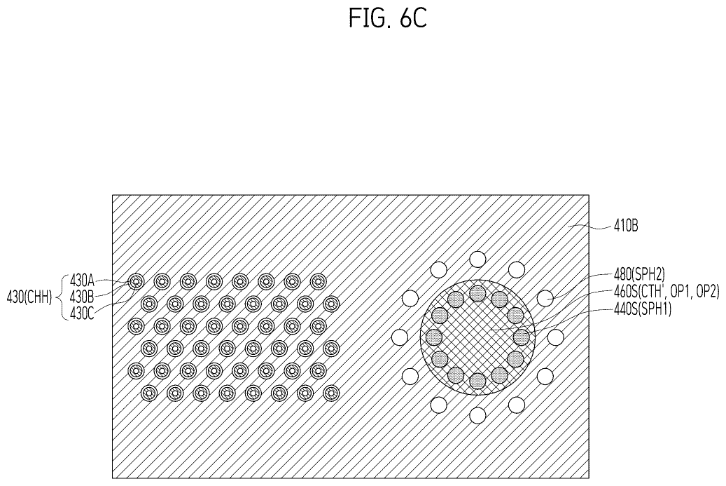

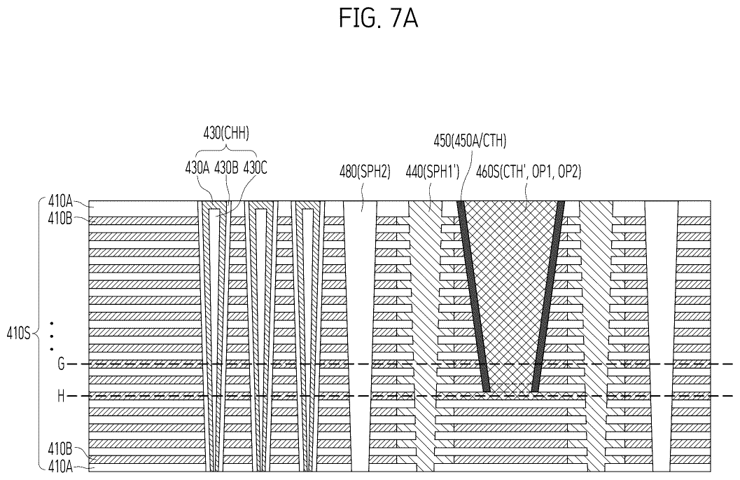

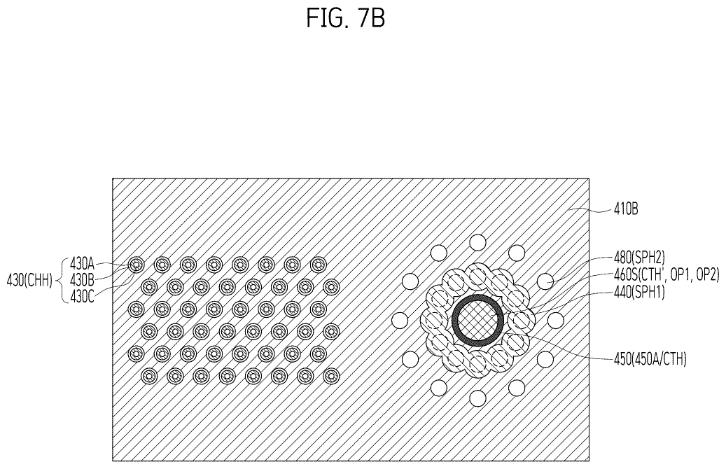

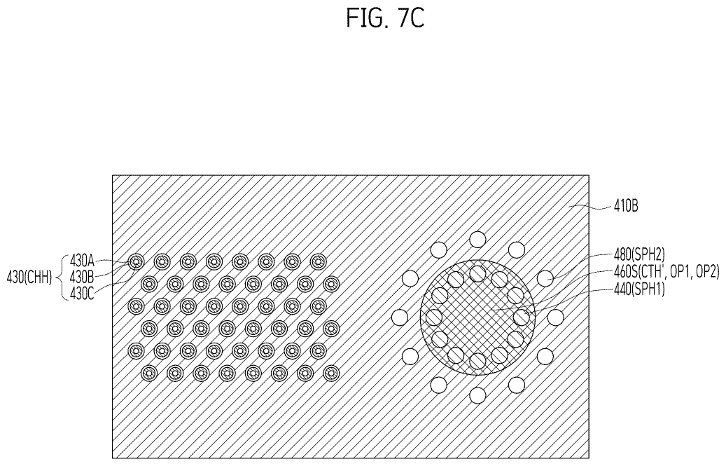

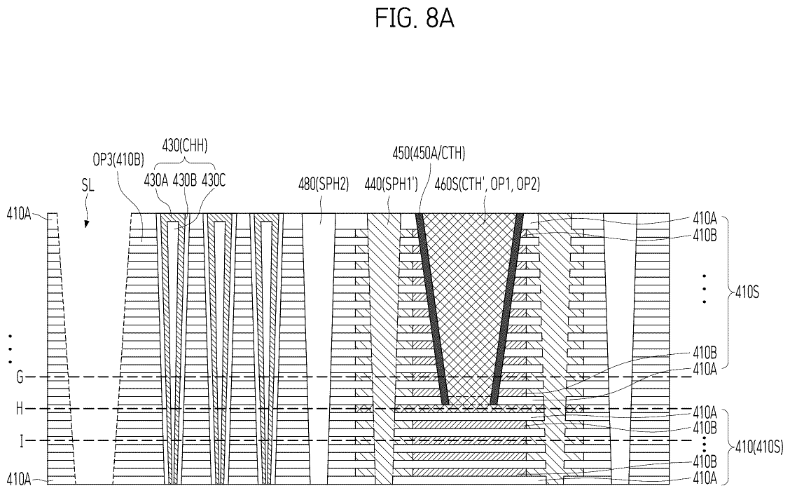

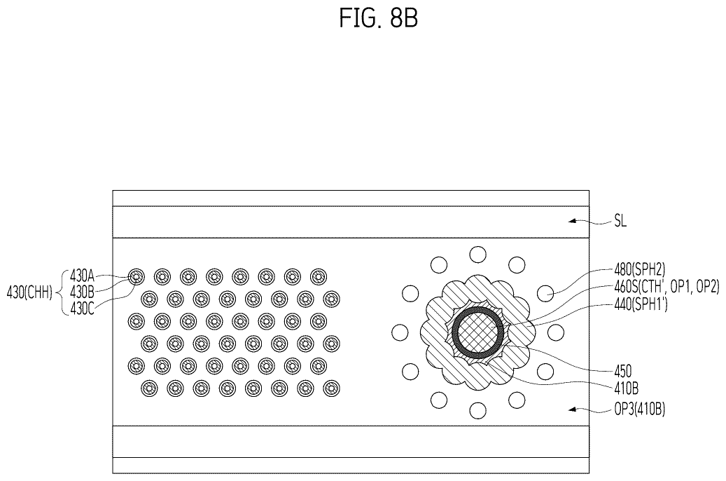

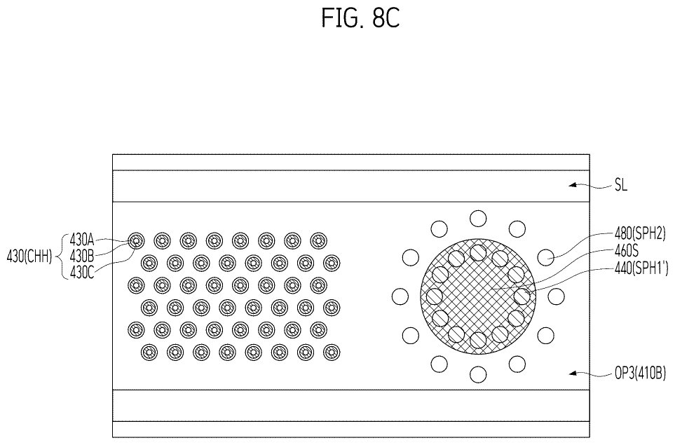

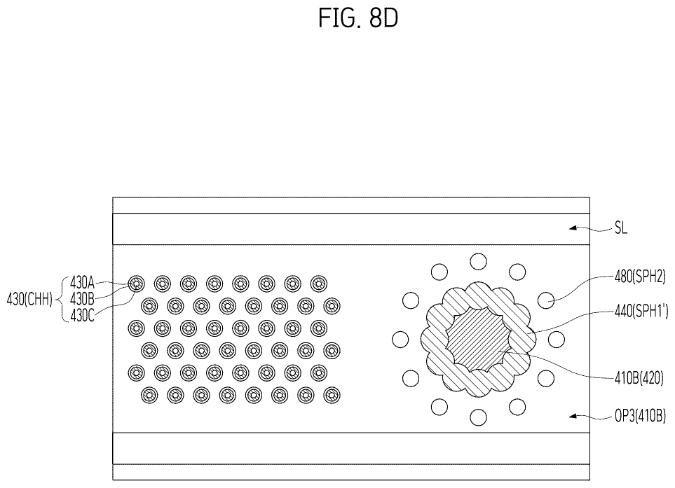

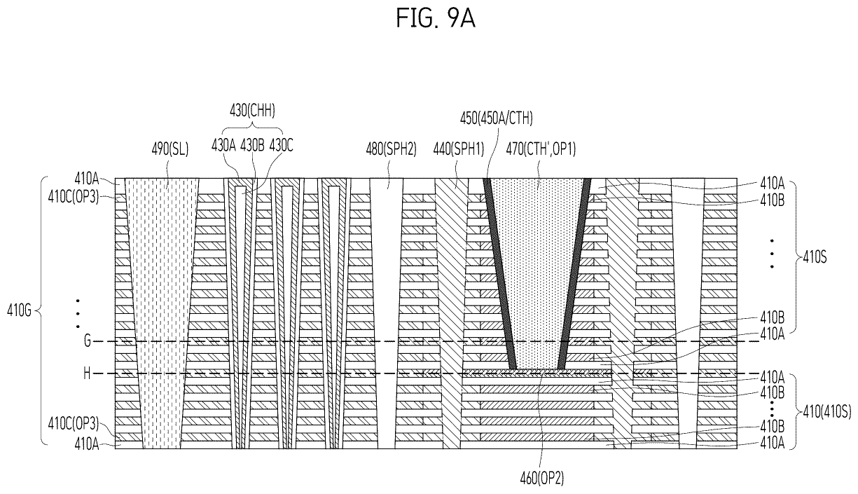

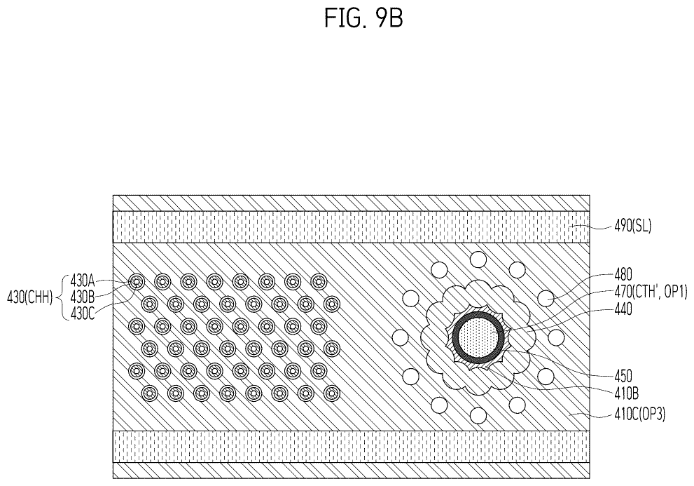

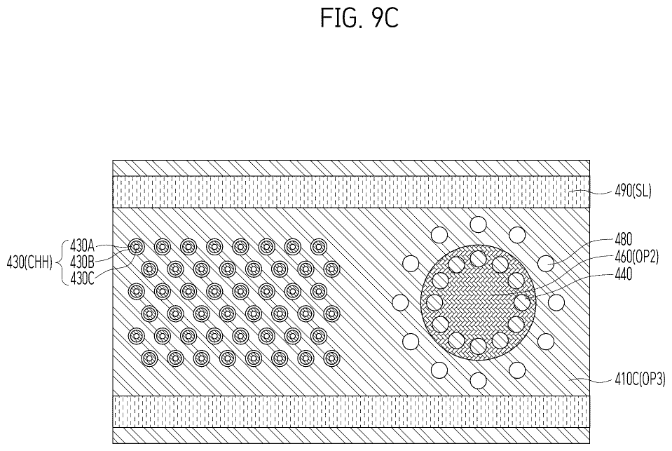

FIG. 4A, FIG. 4B, FIG. 5A, FIG. 5B, FIG. 5C, FIG. 6A, FIG. 6B, FIG. 6C, FIG. 7A, FIG. 7B, FIG. 7C, FIG. 8A, FIG. 8B, FIG. 8C, FIG. 8D, FIG. 9A, FIG. 9B, and FIG. 9C illustrate a semiconductor device formed utilizing a method of manufacturing a semiconductor device according to an embodiment of the present disclosure. FIG. 4A, FIG. 5A, FIG. 6A, FIG. 7A, FIG. 8A, and FIG. 9A are cross-sectional views, FIG. 4B, FIG. 5B, FIG. 6B, FIG. 7B, FIG. 8B, and FIG. 9B are plan views at level G of FIG. 4A, FIG. 5A, FIG. 6A, FIG. 7A, FIG. 8A, and FIG. 9A, respectively, FIG. 5C, FIG. 6C, FIG. 7C, FIG. 8C, and FIG. 9C are plan views at level H of FIG. 5A, FIG. 6A, FIG. 7A, FIG. 8A, and FIG. 9A, respectively, and FIG. 8D is a plan view at level I of FIG. 8A. Hereinafter, a contact that overlaps the content described above is omitted.

Referring to FIG. 4A and FIG. 4B, a stack 410S is formed by alternately stacking first material layers 410A with second material layers 410B. The first material layers 410A and the second material layers 410B may include different materials. For example, the first material layers 410A may include an insulating material such as an oxide, and the second material layers 410B may include a material such as a nitride.

Channel holes CHH are formed extending through the stack 410S. First support holes SPH1, referred as first holes, are formed extending through the stack 410S. Second support holes SPH2, referred as second holes, are formed extending through the stack 410S. The term “support hole” does not indicate that a support hole provides physical support but rather is so named because the process of forming a support or other supporting structure utilizes the support hole. The first support holes SPH1 and/or the second support holes SPH2 may be formed while the channel holes CHH are formed. The present disclosure is not limited to this example, and the channel holes CHH, the first support holes SPH1 and/or the second support holes SPH2 may be formed at different times.

The first support holes SPH1 are formed in a region where a contact hole is formed in a subsequent process. The region where the contact hole is formed is a region SPHR delineated by the first support holes SPH1. The second support holes SPH2 are formed around the first support holes SPH1.

A channel structure 430 is formed in each of the channel holes CHH. Each of the channel structures 430 includes a channel layer 430A, a memory layer 430B surrounding the channel layer 430A, and an insulating core 430C surrounded by the channel layer 430A.

A supports 480 is formed in each of the second support holes SPH2. The supports 480 may be formed while the channel structures 430 are formed. In this example, the supports 480 have a structure similar to the channel structures 430. For example, each of the supports 480 includes at least one of a dummy channel layer, a dummy memory layer surrounding the dummy channel layer, and a dummy insulating core surrounded by the dummy channel layer. The present disclosure is not limited to this example, and the supports 480 may be formed at a time different from a time when the channel structures 430 are formed. In this example, the supports 480 may include an insulating material such as an oxide. Alternatively, the supports 480 may include a conductive layer such as tungsten and an insulating layer covering the conductive layer.

Support sacrificial layers 440S are formed in the first support holes SPH1. The support sacrificial layers 440S may include a material such as carbon or polysilicon.

Referring to FIG. 5A to FIG. 5C, a contact hole CTH extending through the stack 410S is formed. For example, the contact hole CTH is formed within the region SPHR delineated by the first support holes SPH1 and extends through the stack 410S. One of the first material layers 410A is exposed through the contact hole CTH.

A preliminary contact spacer 450A is formed in the contact hole CTH. For example, the preliminary contact spacer 450A is conformally formed adjacent to the stack 410S within the contact hole CTH. The preliminary contact spacer 450A may include an insulating material such as an oxide.

A first opening OP1 is formed, for example, by etching a lowermost surface of the preliminary contact spacer 450A, the second material layer 410B is exposed through the first opening OP1, and the auxiliary contact hole CTH′ within the resulting contact spacer 450. The contact spacer 450 of a contact plug may be formed by etching the lowermost surface of the preliminary contact spacer 450A.

A second opening OP2 is formed by selectively removing the second material layer 410B through the first opening OP1. For example, the second opening OP2 is formed by selectively removing the second material layer 410B such that the support sacrificial layers 440S are exposed through the first opening OP1.

Referring to FIG. 6A to FIG. 6C, a contact sacrificial layer 460S is formed within the second opening OP2, within the first opening OP1, and within the spacer 450 that is formed in the contact hole CTH. For example, the contact sacrificial layer 460S is formed to fill the second opening OP2, the first opening OP1, and the spacer 450 that is formed in the contact hole CTH. The contact sacrificial layer 460S may include a material such as carbon or polysilicon.

Referring to FIG. 7A to FIG. 7C, the support sacrificial layers 440S are removed, resulting in auxiliary first support holes SPH1′. The auxiliary first support holes SPH1′ are expanded by selectively removing the second material layers 410B through the auxiliary first support holes SPH1′. For example, the auxiliary first support holes SPH1′ are expanded such that the auxiliary first support holes SPH1′ are contiguous, adjoining, or interconnected. In this example, the auxiliary first support holes SPH1′ are expanded to form a single contiguous auxiliary support hole. In the example shown in the drawings, the contiguous auxiliary support hole is generally ring-shaped, with a chain of expanded holes distributed evenly around the ring.

A separation structure 440 is formed in the contiguous auxiliary support hole. In this example, the separation structure 440 forms a closed region within the region SPHR delineated by the contiguous auxiliary support hole. The separation structure 440 separates a region where the contact hole CTH is formed in a region where a gate structure is located. The separation structure 440 may include an insulating material such as an oxide.

Referring to FIG. 8A to FIG. 8D, a slit SL is formed extending through the stack 410S. The slit SL may have a rectangular shape, where two sides of the rectangle are shown horizontally in the plan views of FIG. 8B, FIG. 8C, and FIG. 8D and another side of the rectangle is shown vertically in the cross-sectional view of FIG. 8A. Third openings OP3 are formed by removing the second material layers 410B through the slit SL. The separation structure 440 is exposed through at least one of the third openings OP3. The contact sacrificial layer 460S is exposed through one of the third openings OP3. In this example, the stack 410S remains in the region where the contact hole CTH is formed by the separation structure 440. The stack 410S located under the contact hole CTH is referred to as a support structure 410.

Referring to FIG. 9A to FIG. 9C, third material layers 410C are formed in the third openings OP3. The third material layers 410C are used as gate lines and may include a conductive material such as tungsten. A gate structure 410G is formed including the first material layers 410A alternately stacked with the third material layers 410C.

Height of the stack may be increased and height of a gate structure may be increased to improve integration density of a semiconductor device. Accordingly, a target height of a contact hole used to form a contact plug connected to the gate line of the gate structure increases, and a width of the contact hole increases. In this example, as a region area where the contact hole is formed increases, a region where supports supporting the stack are formed decreases, thus the stack may bend when removing second material layers during a process of forming the gate structure. Because the supports are not formed under the contact hole, the stack may not be sufficiently supported under the contact hole.

According to an embodiment of the present disclosure, the first support holes SPH1 may be formed in a region where the contact hole CTH is subsequently formed. Because the first support holes SPH1 are formed to form the support structure 420 under the contact hole CTH, the first support holes SPH1 are formed around the contact hole CTH, for example, to surround the contact hole CTH. The separation structure 440 is formed by expanding the auxiliary first support holes SPH1 such that the expanded auxiliary first support holes SPH1 form a single contiguous auxiliary support hole, and the stack 410S remains within the separation structure 440. The stack 410S located under the contact hole CTH is used as the support structure 420. According to an embodiment of the present disclosure, during a process of removing the second material layers 410B to form the gate structure 410G bending of the semiconductor device may be prevented or reduced by use of the separation structure 440, the stack 410S, and the support structure 420.

A slit structure 490 is formed in the slit SL. The slit structure 490 may include at least one of an insulating material, a semiconductor material, and a conductive material.

The auxiliary contact hole CTH′, the first opening OP1, and the second opening OP2 are formed by removing the contact sacrificial layer 460S formed within the spacer 450, the first opening OP1, and the second opening OP2. A conductive material is formed in the auxiliary contact hole CTH′, the first opening OP1, and the second opening OP2. The conductive material may include a conductive material such as tungsten or polysilicon.

A contact pattern 460 is formed in a location of the second opening OP2. A contact plug 470 is formed in a location of the first opening OP1 and the auxiliary contact hole CTH′. In this example, the contact pattern 460 is connected to the third material layer 410C by extending in a horizontal direction around the separation structure 440, and the contact plug 470 is connected to the third material layer 410C through the contact pattern 460.

According to an embodiment of the present disclosure, the stack 410S in which the contact plug 470 is formed and the gate structure 410G are separated by the separation structure 440. In this example, the contact plug 470 and one of the third material layers 410C of the gate structure 410G are connected. According to an embodiment of the present disclosure, the contact pattern 460 extends in the horizontal direction to connected to one of the third material layers 410C, thus the contact plug 470 and the third material layer 410C are electrically connected.

Although the figures show an example including one contact plug 470, the quantity of contact plugs 470 is not limited to this example. For example, the quantity of contact plugs may be equal to the quantity of third material layers 410C. In this example, the contact plugs are connected to the third material layers 410C through corresponding contact patterns and have different heights. A support structure is formed under each contact plug.

According to the described method of manufacturing a semiconductor device, the first support holes SPH1 are formed in the region where the contact hole CTH is subsequently formed, and one contiguous auxiliary support hole is formed by expanding the first support holes SPH1 such that the expanded first support holes SPH1 are contiguous or interconnected. In this example, the stack 410S remains within the region SPHR delineated by the contiguous auxiliary support hole formed from first support holes SPH1, and the stack 410S is used as a support structure that prevents the stack 410S from bending during a process of forming the gate structure 410G.

The separation structure 440 is formed in the contiguous auxiliary support hole. In this example, the stack 410S and the gate structure 410G are separated by the separation structure 440. The contact pattern 460 extends in the horizontal direction around the separation structures 440 to electrically connect the contact plug 470 and one of the third material layers 410C of the gate structure 410G.

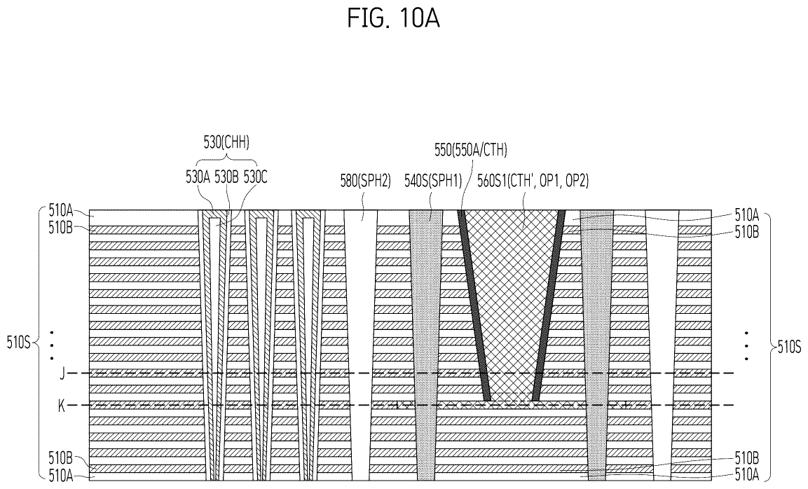

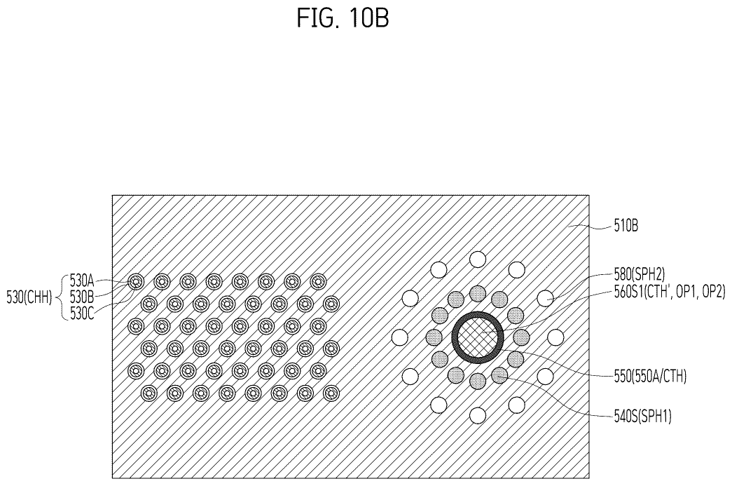

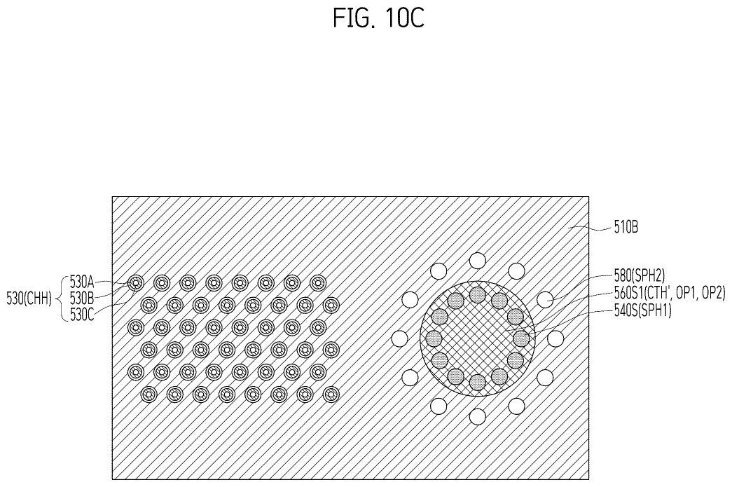

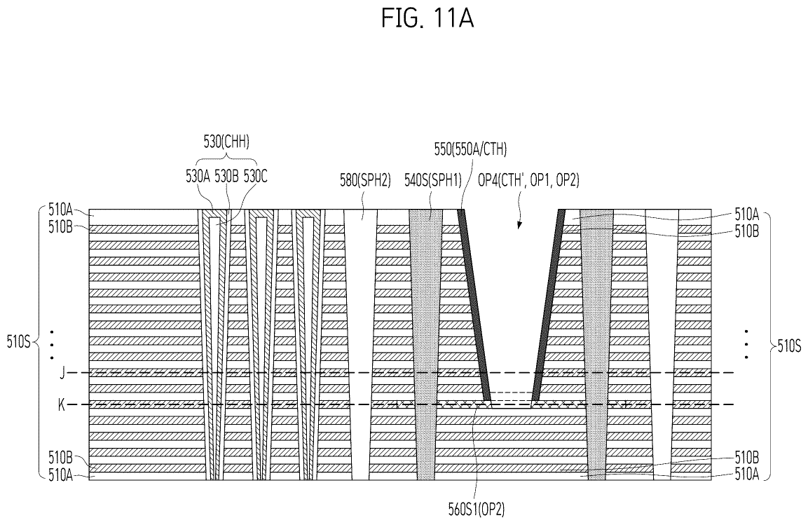

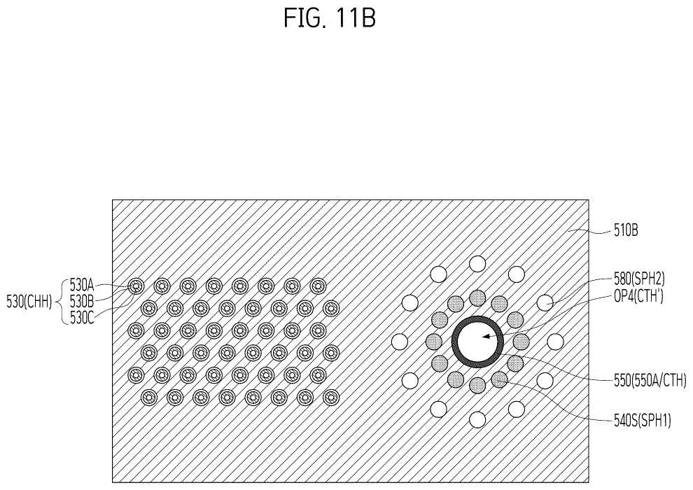

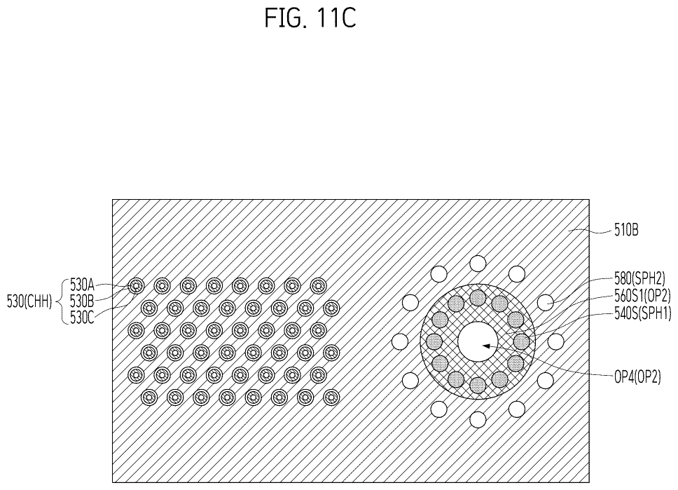

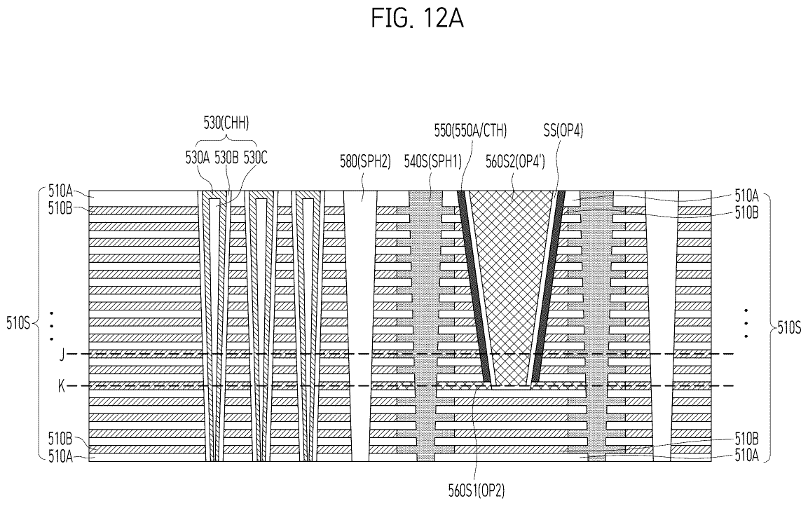

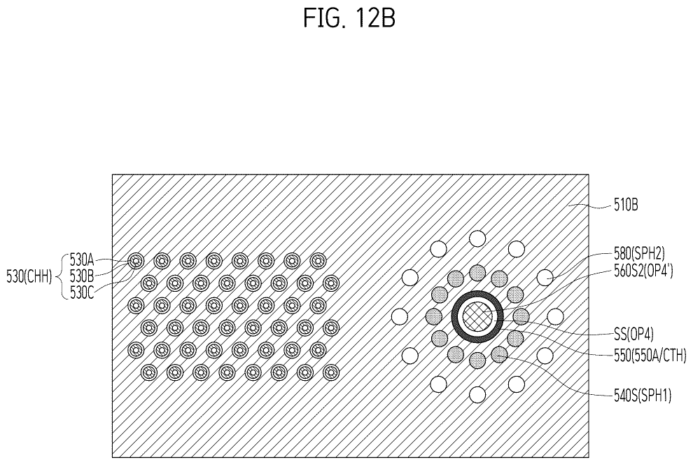

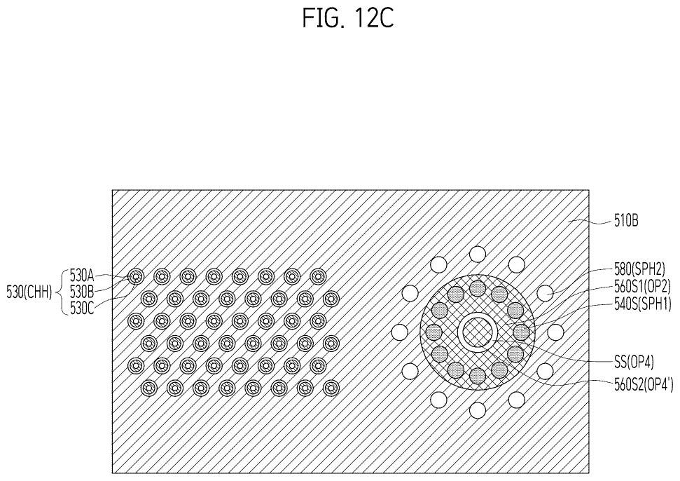

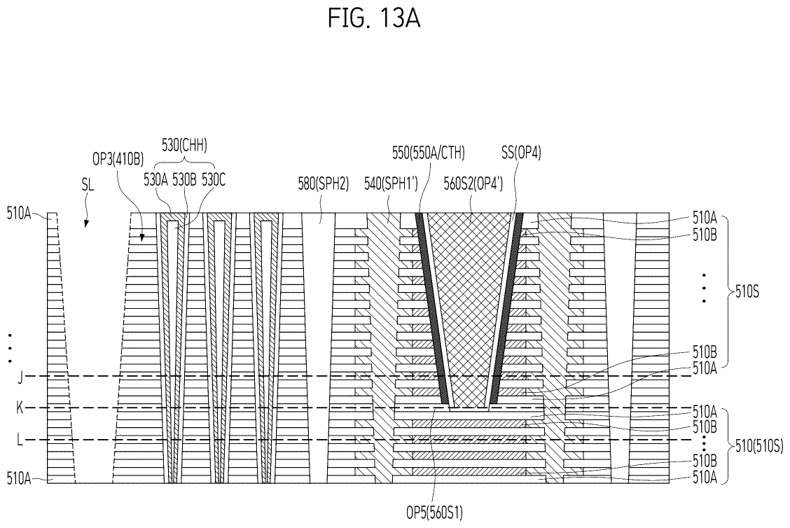

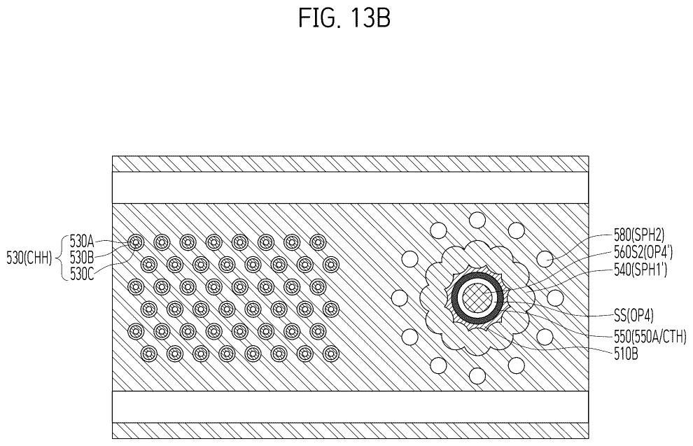

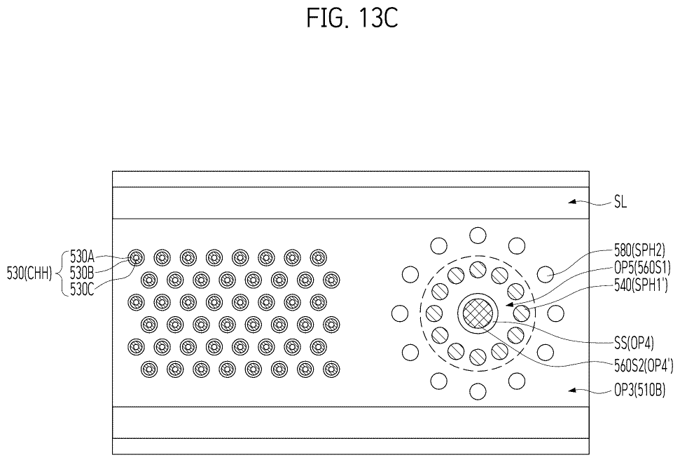

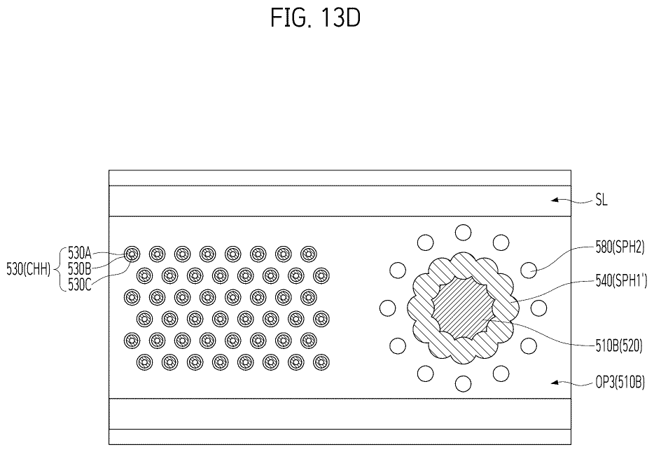

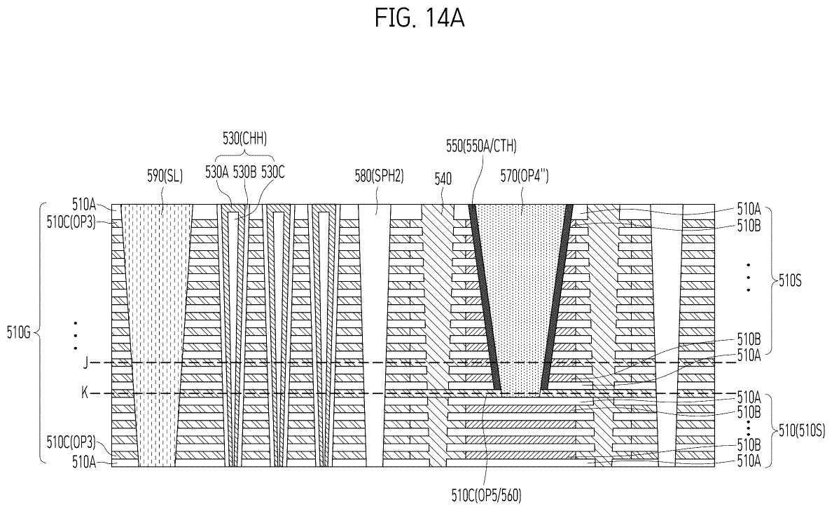

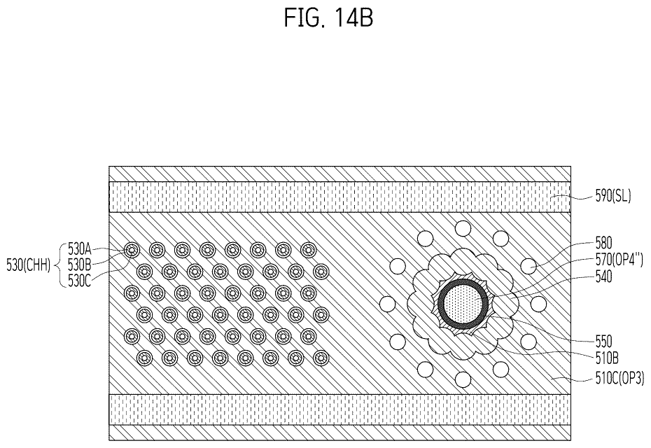

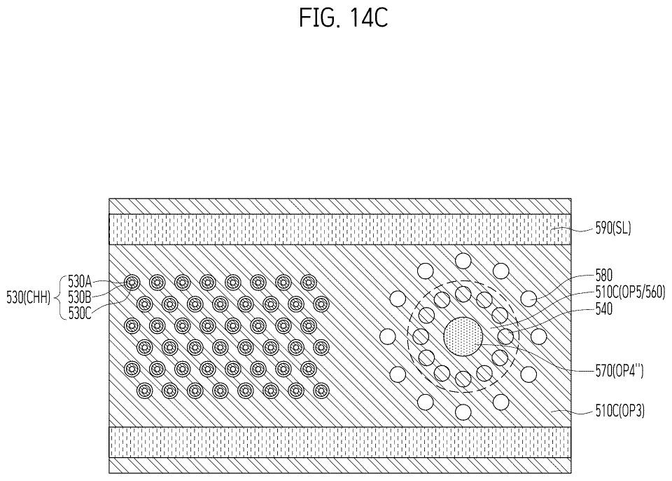

FIG. 10A, FIG. 10B, FIG. 10C, FIG. 11A, FIG. 11B, FIG. 11C, FIG. 12A, FIG. 12B, FIG. 12C, FIG. 13A, FIG. 13B, FIG. 13C, FIG. 13D, FIG. 14A, FIG. 14B, and FIG. 14C illustrate a semiconductor device formed utilizing a method of manufacturing a semiconductor device according to an embodiment of the present disclosure. FIG. 10A, FIG. 11A, FIG. 12A, FIG. 13A, and FIG. 14A are cross-sectional views, FIG. 10B, FIG. 11B, FIG. 12B, FIG. 13B, and FIG. 14B are plan views at level J of FIG. 10A, FIG. 11A, FIG. 12A, FIG. 13A, and 1 FIG. 4A, respectively, and FIG. FIG. 10C, FIG. 11C, FIG. 12C, FIG. 13C, and FIG. 14C are plan views at level K of FIG. 10A, FIG. 11A, FIG. 12A, FIG. 13A, and FIG. 14A, respectively, and FIG. 13D is a plan view at level L of FIG. 13a. Hereinafter, a contact that overlaps the content described above is omitted.

Referring to FIG. 10A to FIG. 10C, a stack 510S is formed by alternately stacking first material layers 510A with second material layers 510B. The first material layers 510A may include an insulating material such as an oxide, and the second material layers 510B may include a material such as a nitride.

Channel structures 530 are formed within channel holes CHH extending through the stack 510S. Each of the channel structures 530 includes a channel layer 530A, a memory layer 530B surrounding the channel layer 530A, and an insulating core 530C surrounded by the channel layer 530A.

Supports 580 are formed in second support holes SPH2 extending through the stack 510S. The supports 580 may have a structure similar to the channel structures 530. Alternatively, the supports 580 may include an insulating material such as an oxide. Alternatively, the supports 580 may include a conductive layer such as tungsten and an insulating layer surrounding the conductive layer.

Support sacrificial layers 540S are formed in first support holes SPH1 extending through the stack 510S. The support sacrificial layers 540S may include a material such as carbon or polysilicon.

A contact hole CTH is formed extending through the stack 510S. For example, the contact hole CTH is formed in a region delineated by the first support holes SPH1 and extending through the stack 510S.

A preliminary contact spacer 550A is formed in the contact hole CTH. A first opening OP1 is formed by etching a lower surface of the preliminary contact spacer 550A, thereby exposing the second material layer 510B. A contact spacer 550 of a contact plug may be formed by etching the lowermost surface of the preliminary contact spacer 550A. A second opening OP2 is formed by selectively removing the second material layer 510B such that the support sacrificial layers 540S are exposed through the first opening OP1.

A first contact sacrificial layer 560S1 is formed in the second opening OP2, the first opening OP1, and the auxiliary contact hole CTH′. For example, the first contact sacrificial layer 560S1 is formed to fill the second opening OP2, the first opening OP1, and the auxiliary contact hole CTH′. The first contact sacrificial layer 560S1 may include a material such as carbon or polysilicon.

Referring to FIG. 11A to FIG. 11C, a fourth opening OP4 is be formed by removing a portion of the first contact sacrificial layer 560S1. For example, the fourth opening OP4 is formed by removing a portion of the first contact sacrificial layer 560S1 formed in the auxiliary contact hole CTH′, the first opening OP1, and the second opening OP2. A portion of the first contact sacrificial layer 560S1 formed at a location corresponding to the first opening OP1 and a location corresponding to the second opening OP2 is removed. For example, a portion of the first contact sacrificial layer 560S1 formed in the second opening OP2 remains. Auxiliary first openings and auxiliary second openings result from removal of the first contact sacrificial layer 560S1.

Referring to FIG. 12A to FIG. 12C, a sacrificial spacer SS is formed in the fourth opening OP4. For example, the sacrificial spacer SS is conformally formed along the contact spacer 550 and within the fourth opening OP4. The sacrificial spacer SS may include a material different from a material of the contact spacer 550. For example, the sacrificial spacer SS may include a nitride, and the contact spacer 550 may include an oxide.

A second contact sacrificial layer 560S2 is formed in the auxiliary fourth opening OP4′ that results from forming the sacrificial spacer SS within the fourth opening OP4. For example, the second contact sacrificial layer 560S2 is formed on the sacrificial spacer SS. The second contact sacrificial layer 560S2 may include a material substantially similar to a material included in the first contact sacrificial layer 560S1. For example, the second contact sacrificial layer 560S2 may include a material such as carbon or polysilicon. The present disclosure is not limited to this example, and the second contact sacrificial layer 560S2 may include a material different from the material of the first contact sacrificial layer 560S1.

Referring to FIG. 13A to FIG. 13D, the support sacrificial layers 540S are removed, resulting in auxiliary support holes SPH1′. The auxiliary first support holes SPH1′ are expanded by selectively removing the second material layers 510B through the auxiliary first support holes SPH1′. For example, the auxiliary first support holes SPH1′ are expanded such that the first auxiliary support holes SPH1′ are contiguous or interconnected. In this example, the auxiliary first support holes SPH1′ are expanded to form one contiguous auxiliary support hole SPH1. A separation structure 540 is formed within the contiguous auxiliary support hole. The separation structure 540 separates a region where the contact hole CTH is formed from another region such as a gate structure.

A slit SL is formed extending through the stack 510S. Third openings OP3 are formed by removing the second material layers 510B through the slit SL. The separation structure 540 is exposed through at least one of the third openings OP3. The first contact sacrificial layer 560S1 is exposed through one of the third openings OP3. In other words, the first contact sacrificial layer 560S1 remaining in the second opening OP2 is exposed through one of the third openings OP3. In this example, the stack 510S remains in the region where the contact hole CTH is formed within the separation structure 540. The stack 510S located under the contact hole CTH is referred to as a support structure 520.

A fifth opening OP5 is formed by removing the first contact sacrificial layer 560S1 through the third opening OP3 through which the first contact sacrificial layer 560S1 is exposed. For example, the fifth opening OP5 is formed by selectively removing the first contact sacrificial layer 560S1 through the third opening OP3. The sacrificial spacer SS prevents simultaneous removal of the second contact sacrificial layer 560S2 during a process of removing the first contact sacrificial layer 560S1.

Referring to FIG. 14A to FIG. 14C, third material layers 510C are formed in the third openings OP3. The third material layer 510C is formed in the fifth opening OP5. When forming the third material layers 510C in the third openings OP3, the third material layer 510C may be formed in the fifth opening OP5. The third material layer 510C formed in the fifth opening OP5 is referred to as a contact pattern 560. The third material layers 510C are used as gate lines and may include a conductive material such as tungsten. Thus, a gate structure 510G is formed including the first material layers 510A alternately stacked the third material layers 510C.

A slit structure 590 is formed within the slit SL. The slit structure 590 may include at least one of an insulating material, a semiconductor material, and a conductive material.

A fourth opening OP4″ is opened by removing the second contact sacrificial layer 560S2 and the sacrificial spacer SS. For example, the fourth opening OP4″ is opened by sequentially removing the second contact sacrificial layer 560S2 and the sacrificial spacer SS.

A contact plug 570 is formed by forming a conductive material in the fourth opening OP4″. In this example, the contact plug 570 is connected to one of the third material layers 510C of the gate structure 510G through the contact pattern 560. The conductive material may include a conductive material such as tungsten or polysilicon.

When removing the first contact sacrificial layer formed in the second opening through the contact hole and the first opening, the first contact sacrificial layer formed in the second opening might not be completely removed. When forming a conductive material, the conductive material might not be completely formed in the second opening extending in a horizontal direction. In this example, the contact plug and the third material layer might not be electrically connected, resulting in a defect.

According to an embodiment of the present disclosure, the fourth opening OP4 are formed by removing a portion of the first contact sacrificial layer 560S1 formed in the contact hole CTH, the first opening OP1, and the second opening OP2. A portion of the first contact sacrificial layer 560S1 formed in the second opening OP2 may remain.

A sacrificial spacer SS is formed in the fourth opening OP4, and a second contact sacrificial layer 560S2 is formed on the sacrificial spacer SS. After forming the third openings OP3 to form the gate structure 510G, the fifth opening OP5 is formed by removing the first contact sacrificial layer 560S1 exposed by one of the third openings OP3. In this example, the first contact sacrificial layer 560S1 is removed and none of the first contact sacrificial layer 560S1 remains in the second opening OP2.

Third material layers 510C are formed in the third openings OP3 and the fifth opening OP5. In this example, when forming the third material layers 510C in the third openings OP3, the third material layer 510C is formed in the fifth opening OP5, thus a conductive material is formed in the fifth opening OP5 in the horizontal direction. Thus, the contact plug 570 and the third material layer 510C may be consistently electrically connected.

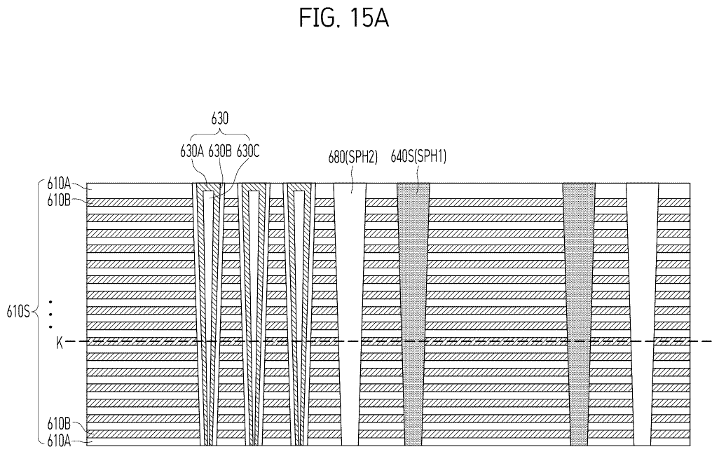

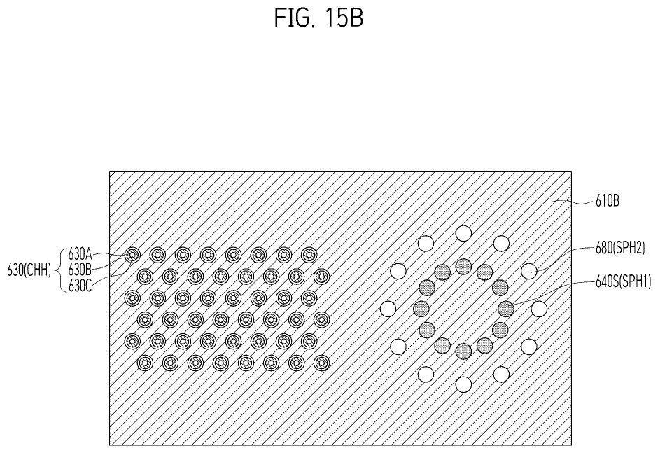

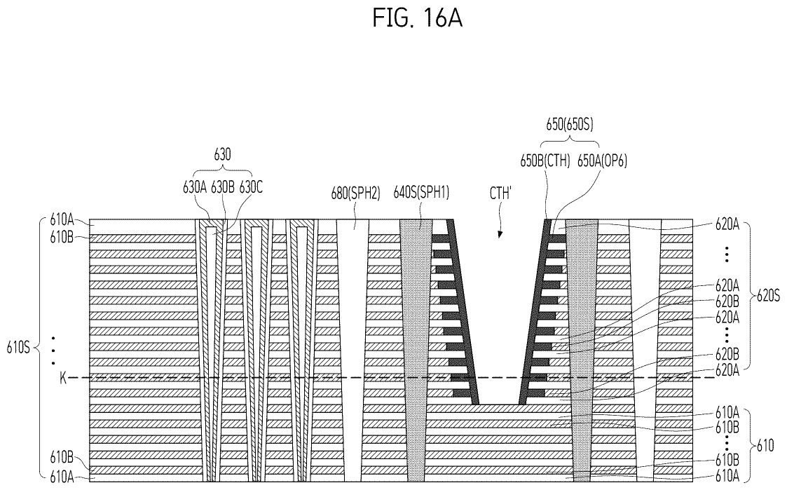

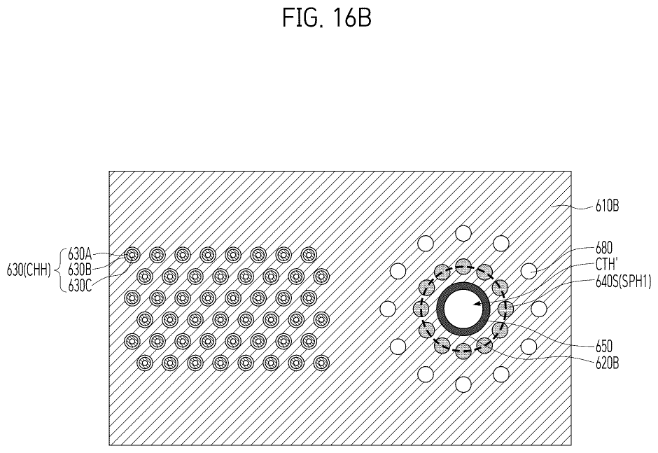

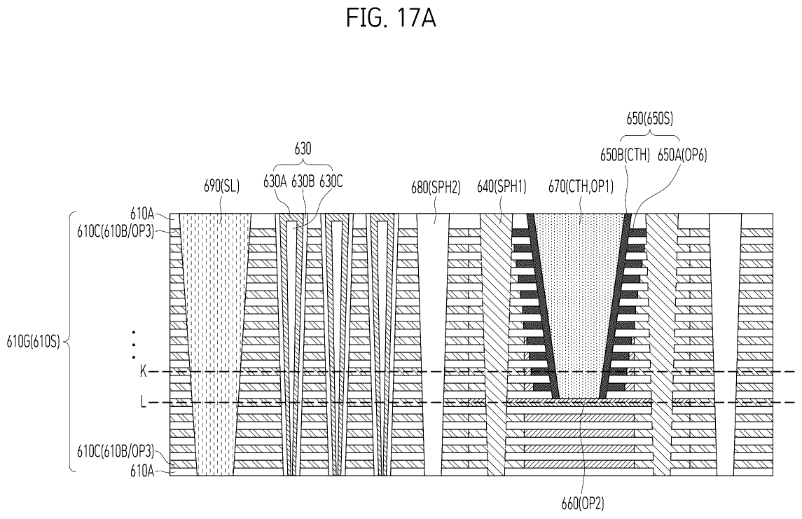

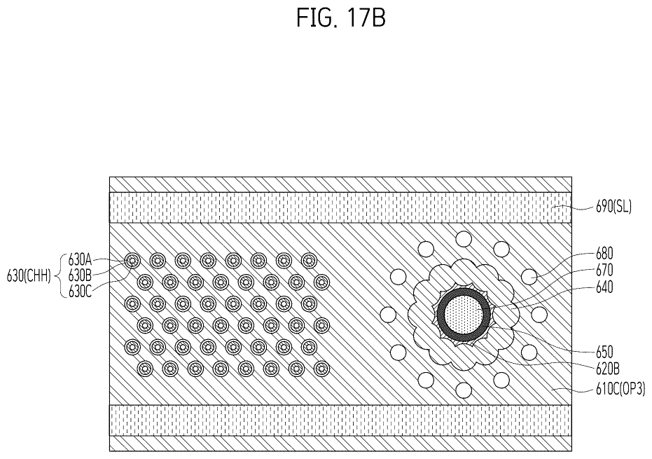

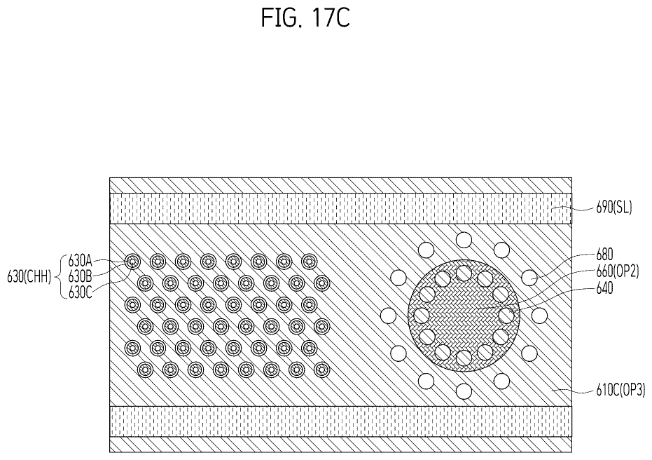

FIG. 15A, FIG. 15B, FIG. 16A, FIG. 16B, FIG. 17A, FIG. 17B, and FIG. 17C illustrate a semiconductor device formed utilizing a method of manufacturing a semiconductor device according to an embodiment of the present disclosure. FIG. 15A, FIG. 16A, and FIG. 17A are cross-sectional views, FIG. 15B, FIG. 16B, and FIG. 17B are plan views at level K of FIG. 15A, FIG. 16A, and FIG. 17A, respectively, and FIG. 17C is a plan view at level L of FIG. 17A.

Referring to FIG. 15A and FIG. 15B, a stack 610S is formed by alternately stacking first material layers 610A with second material layers 610B. The first material layers 610A may include an insulating material such as an oxide, and the second material layers 610B may include a material such as a nitride.

Channel structures 630 extending through the stack 610S are formed. Each of the channel structures 630 includes a channel layer 630A, a memory layer 630B surrounding the channel layer 630A, and an insulating core 630C surrounded by the channel layer 630A.

Supports 680 extending through the stack 610S are formed. The supports 680 may have a structure similar to the channel structures 630. Alternatively, the supports 680 may include an insulating material such as an oxide. Alternatively, the supports 680 may include a conductive layer such as tungsten and an insulating layer surrounding the conductive layer.

Support sacrificial layers 640S extending through the stack 610S are formed. The support sacrificial layers 640S may include a material such as carbon or polysilicon.

Referring to FIG. 16A and FIG. 16B, a contact hole CTH extending through the stack 610S is formed. For example, the contact hole CTH is formed within a region delineated by the first support holes SPH1 and extending through the stack 610S. The stack 620S within the region includes first insulating layers 620A insulating layers second insulating layers 620B.

Sixth openings OP6 are formed by selectively removing the second material layers 610B through the contact hole CTH. For example, the sixth openings OP6 are formed by removing a portion of the second material layers 610B exposed through the contact hole CTH. The support sacrificial layers 640S are exposed through at least one of the sixth openings OP6.

A preliminary contact spacer 650S is formed in the sixth openings OP6 and the contact hole CTH. The preliminary contact spacer 650S may fill the sixth openings OP6 and is conformally formed adjacent to the stack 620S and within the contact hole CTH. A first opening OP1 is formed, for example, by etching a lowermost surface of the preliminary contact spacer 650A, the second material layer 610B is exposed through the first opening OP1, and the auxiliary contact hole CTH′ results within the contact spacer 650. The contact spacer 650 of a contact plug may be formed by etching the lowermost surface of the preliminary contact spacer 650A. For example, the contact spacer 650 is formed including a body 650B formed in the contact hole CTH, and protrusions 650A protruding or extending from the body 650B are formed in the sixth openings OP6.

Referring to FIG. 17A to FIG. 17C, supports 640, a contact pattern 660, a contact plug 670, and a slit structure 690 are formed. The supports 640, the contact pattern 660, the contact plug 670, and the slit structure 690 may be formed using a method similar to a method used to form the supports 440, the contact pattern 460, the contact plug 470, and the slit structure 490 formed with reference to FIG. 5A to FIG. 9C.

According to an embodiment of the present disclosure, after forming the contact hole CTH, the sixth openings OP6 are formed by selectively removing the second material layers 610B exposed through the contact hole CTH. The contact spacer 650 is formed in the sixth openings OP6.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A semiconductor device comprising:
a stack including a plurality of first insulating layers alternately stacked with a plurality of second insulating layers;
a contact plug extending through the stack;
a gate structure surrounding the stack and including a plurality of conductive layers alternately stacked with the plurality of first insulating layers;
a separation structure located between the stack and the gate structure; and
a contact pattern extending around the separation structure and electrically connecting the contact plug and a first conductive layer among the plurality of conductive layers.

2. The semiconductor device of claim 1, wherein the separation structure comprises:
a plurality of pillars arranged around the contact plug; and
a plurality of extensions interconnecting the pillars and located at levels corresponding to the plurality of conductive layers except for the first conductive layer.

3. The semiconductor device of claim 2, wherein the plurality of extensions are interconnected in a plane to form a closed region.

4. The semiconductor device of claim 3, wherein one of the plurality of second insulating layers is located at a level corresponding to the plurality of extensions and is located in the closed region.

5. The semiconductor device of claim 2, wherein the contact pattern extends between the plurality of pillars.

6. The semiconductor device of claim 2, wherein the contact pattern is integral with the contact plug.

7. The semiconductor device of claim 1, wherein the contact pattern is integral with the first conductive layer.

8. The semiconductor device of claim 1, further comprising a contact spacer surrounding a sidewall of the contact plug.

9. The semiconductor device of claim 8, wherein the contact spacer includes a body extending through the stack and protrusions protruding from the body toward the gate structure.

10. The semiconductor device of claim 1, further comprising:
a plurality of channel structures extending through the gate structure; and
a slit structure extending through the gate structure.

11. A semiconductor device comprising:
a stack including a plurality of first insulating layers alternately stacked with a plurality of second insulating layers;
a contact plug extending through the stack;
a gate structure surrounding the stack and including a plurality of conductive layers alternately stacked with the plurality of first insulating layers;
a separation structure located between the stack and the gate structure and including a plurality of pillars arranged around the contact plug and a plurality of extensions interconnecting the pillars; and
a contact pattern extending around the separation structure and electrically connecting the contact plug and a first conductive layer among the plurality of conductive layers.

12. The semiconductor device of claim 11, wherein the plurality of extensions are located at levels corresponding to one of the plurality of conductive layers except for the first conductive layer.

13. The semiconductor device of claim 11, wherein the plurality of extensions is interconnected in a plane to form a closed region.

14. The semiconductor device of claim 13, wherein the plurality of second insulating layers is located at levels corresponding to the plurality of extensions and located in the closed region.

15. The semiconductor device of claim 11, wherein the contact pattern extends between the plurality of pillars.

16. The semiconductor device of claim 11, wherein the contact pattern is electrically connected to the contact plug.

17. The semiconductor device of claim 11, wherein the contact pattern is electrically connected to the first conductive layer.

18. The semiconductor device of claim 11, further comprising a contact spacer surrounding a sidewall of the contact plug.

19. The semiconductor device of claim 18, wherein the contact spacer includes a body extending through the stack and protrusions protruding from the body toward the gate structure.

20. The semiconductor device of claim 11, further comprising:
a plurality of channel structures extending through the gate structure; and
a slit structure extending through the gate structure.
